(19) United States
(12) Patent Application Publication
(10) Pub. No.: US 2010/0025799 A1
(43) Pub. Date: Feb. 4, 2010

(54) WAFER FOR BACKSIDE ILLUMINATION TYPE SOLID IMAGING DEVICE, PRODUCTION METHOD THEREOF AND BACKSIDE ILLUMINATION TYPE SOLID IMAGING DEVICE

(75) Inventor: Kazunari Kurita, Minato-ku (JP)

Correspondence Address: CHRISTENSEN, O'CONNOR, JOHNSON, KINDNESS, PLLC, 1420 FIFTH AVENUE, SUITE 2800, SEATTLE, WA, 98101-2347, US

(73) Assignee: SUMCO CORPORATION, Tokyo (JP)

(21) Appl. No.: 12/512,791

(22) Filed: Jul. 30, 2009

(30) Foreign Application Priority Data
Aug. 4, 2008 (JP) 2008-200572

(51) Int. Cl. H01L 27/148; H01L 31/18

(52) U.S. Cl. 257/447; 438/75; 257/E27.15; 257/E21.085

(57) ABSTRACT

A wafer for backside illumination type solid imaging device has a plurality of pixels inclusive of a photoelectric conversion device and a charge transfer transistor at its front surface side and a light receiving surface at its back surface side, wherein said wafer is a SOI wafer obtained by forming a given active layer on a support substrate made of C-containing n-type semiconductor material through a chemical oxide film having a thickness of not more than 1 nm.

### BACKGROUND

1. Field of the Invention

This invention relates to a silicon substrate, a production method thereof and a device using the substrate, and more particularly to a wafer for backside illumination type solid imaging device, which is used in mobile phones, digital video cameras and the like and is capable of suppressing white defects effectively, a production method thereof and a backside illumination type solid imaging device.

2. Description of the Related Art

Recently, a high-performance solid imaging device using a semiconductor is mounted onto a mobile phone, a digital video camera or the like, and hence the performances such as number of pixels and the like are dramatically improved. As the performance to be expected in the usual solid imaging device are high-quality pixels and ability of taking moving images, and further miniaturization is required. In order to take moving images, it is required to combine with a high-speed computing device and a memory device, and hence a CMOS image sensor allowing System on Chip (SoC) easily is used and the downsizing of the CMOS image sensor is developed.

With the downsizing of the CMOS image sensor, however, there is caused a problem that an aperture ratio of a photo diode as a photoelectric conversion device is inevitably reduced to lower a quantum efficiency of the photoelectric conversion device, which makes it difficult to improve S/N ratio of imaging data. Therefore, it is attempted to conduct a method for increasing incident light quantity by inserting an inner lens into a front side of the photoelectric conversion device, or the like. However, the remarkable improvement of S/N ratio can not be realized.

In order to increase the incident light quantity to improve S/N ratio of the image data, therefore, it is attempted to feed the incident light from a backside of the photoelectric conversion device. The greatest merit of the light incidence from the backside of the device lies in a point that restriction due to reflection or diffraction on the surface of the device or the light receiving area of the device is eliminated as compared with the light incidence from the front side. On the other hand, when the light is entered from the backside, the absorption of the light through a silicon wafer as a substrate of the photoelectric conversion device must be suppressed, and hence the thickness of the solid imaging device as a whole is required to be less than 50 μm. As a result, the working and handling of the solid imaging device become difficult, causing a problem of extremely low productivity.

For the purpose of resolving the above technical problems, there are mentioned solid imaging devices as disclosed, for example, in JP-A-2007-13089 and JP-A-2007-59755.

When using the production method of the solid imaging device in JP-A-2007-13089, it is possible to produce a backside illumination type CMOS solid imaging device having a structure that electrodes are taken out from a surface opposite to the illuminated surface relatively simply and easily.

On the other hand, when using the production method of the solid imaging device in JP-A-2007-59755, it is possible to conduct the processing of a thinned solid imaging device with a high accuracy.

In the solid imaging devices of JP-A-2007-13089 and JP-A-2007-59755, however, the gettering ability of the substrate (wafer) is low, so that there are problems that white defects occur and that heavy metal contamination occurs in the production process. Therefore, it is required to solve these problems in order to put the backside illumination type solid imaging device into practical use.

### SUMMARY

This summary is provided to introduce a selection of concepts in a simplified form that are further described below in the Detailed Description. This summary is not intended to identify key features of the claimed subject matter, nor is it intended to be used as an aid in determining the scope of the claimed subject matter.

It is, therefore, an object of the invention to provide a wafer for backside illumination type solid imaging device capable of effectively suppressing the occurrence of white defects and heavy metal contamination, and a production method thereof and a backside illumination type solid imaging device.

In order to achieve the above object, the summary and construction of the invention are as follows.

(1) A wafer for backside illumination type solid imaging device having a plurality of pixels inclusive of a photoelectric conversion device and a charge transfer transistor at its front surface side and a light receiving surface at its back surface side, characterized in that said wafer is a SOI wafer obtained by forming a given active layer on a support substrate made of C-containing n-type semiconductor material through a chemical oxide film having a thickness of not more than 1 nm.

(2) A wafer for backside illumination type solid imaging device according to the item (1), wherein the active layer is an epitaxial layer of Si formed on a substrate for active layer made of C-containing n-type semiconductor material.

(3) A wafer for backside illumination type solid imaging device according to the item (2), wherein a C concentration in each of the support substrate and the substrate for active layer is within a range of 1.0×10¹⁶ to 1.0×10¹⁷ atoms/cm³.

(4) A wafer for backside illumination type solid imaging device according to the item (1), wherein C atoms contained in the support substrate are existent as a high carbon concentration region having a C concentration of 1.0×10¹⁶ to 1.0×10¹⁷ atoms/cm³ just beneath an interface with the chemical oxide film.

(5) A wafer for backside illumination type solid imaging device according to the item (1), wherein the support substrate further contains P, As or Sb.

(6) A backside illumination type solid imaging device comprising an embedded electrode for transferring image data connected to pixels of a wafer for backside illumination type solid imaging device as described in any one of the items (1) to (5).

(7) A method for producing a wafer for backside illumination type solid imaging device having a plurality of pixels inclusive of a photoelectric conversion device and a charge transfer transistor at its front surface side and a light receiving surface at its back surface side, characterized in that a silicon substrate is formed by bonding a wafer for support substrate made of C-containing n-type semiconductor material to a given wafer for active layer through a chemical oxide film having a thickness of not more than 1 nm and then thinning the wafer for active layer.

(8) The method according to the item (7), wherein the wafer for active layer is an epitaxial wafer obtained by forming an epitaxial film of Si on a substrate for active layer made of C-containing n-type semiconductor material.

(9) The method according to the item (8), wherein a C concentration in each of the support substrate and the substrate for active layer is within a range of 1.0×10¹⁶ to 1.0×10¹⁷ atoms/cm³.

(10) The method according to the item (7), wherein each of the wafer for support substrate and the wafer for active layer is subjected to a heat treatment at 600 to 800° C. before bonding thereof.

(11) The method according to the item (7), wherein the bonding is conducted after a given organic substance is adsorbed on a bonding surface of the wafer for support substrate and/or the wafer for active layer.

(12) The method according to the item (11), wherein the organic substance is an organic carbon compound.

(13) The method according to the item (7), wherein a polysilicon film is formed on each surface opposite to bonding surfaces of the wafer for support substrate and the wafer for active layer.

According to the invention, it is possible to provide a wafer for backside illumination type solid imaging device capable of effectively suppressing the occurrence of white defects and heavy metal contamination, a production method thereof and a backside illumination type solid imaging device.

### DESCRIPTION OF THE DRAWINGS

The foregoing aspects and many of the attendant advantages of this invention will become more readily appreciated as the same become better understood by reference to the following detailed description, when taken in conjunction with the accompanying drawings, wherein:

FIGS. 1A and 1B are schematically cross-sectional views of a wafer for backside illumination type solid imaging device according to the invention;

FIG. 2 is a schematically cross-sectional view of a backside illumination type solid imaging device of the invention;

FIG. 3 is a schematically cross-sectional view of a wafer for active layer used in a wafer for backside illumination type solid imaging device according to the invention; and

FIG. 4 is a schematic flow chart of steps for producing a wafer for backside illumination type solid imaging device according to the invention, wherein (a) is a wafer for active layer, (b) is a wafer for active layer provided with a chemical oxide film having a thickness of not more than 1 nm formed thereon, (c) is a wafer for support substrate, (d) is a state of bonding a wafer for active layer to a wafer for support substrate, and (e) is a wafer for backside illumination type solid imaging device according to the invention.

### DETAILED DESCRIPTION

While illustrative embodiments have been illustrated and described, it will be appreciated that various changes can be made therein without departing from the spirit and scope of the invention.

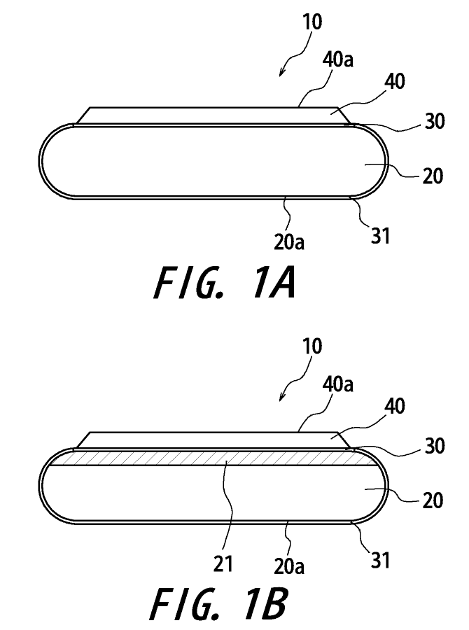

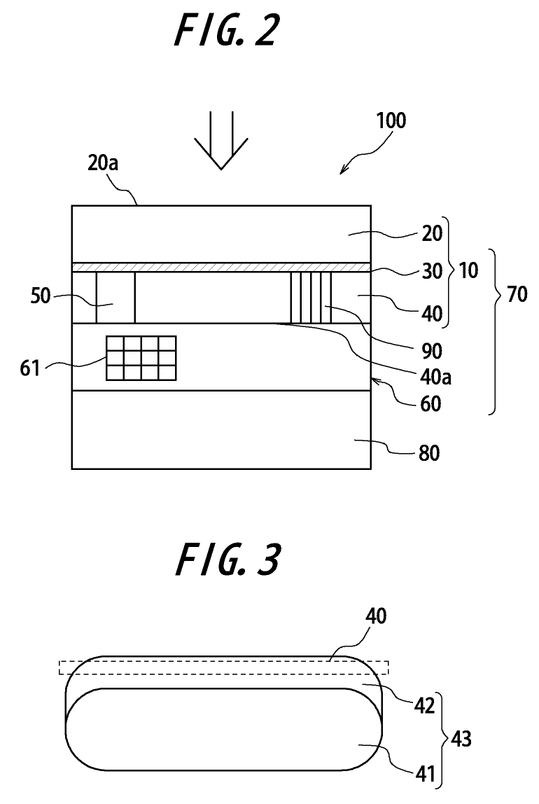

A wafer for backside illumination type solid imaging device according to the invention will be described with the reference to the drawing. Each of FIGS. 1A and 1B is a schematically cross-sectional view of a wafer for backside illumination type solid imaging device according to the invention. Further, FIG. 2 is a schematically cross-sectional view of a backside illumination type solid imaging device using the wafer for backside illumination type solid imaging device shown FIG. 1A after processing thereof.

The wafer 10 for backside illumination type solid imaging device according to the invention is a wafer 10 used in a backside illumination type solid imaging device 100 having a plurality of pixels 70 inclusive of a photoelectric conversion device 50 and a charge transfer transistor 60 at its front surface side 40a and a light receiving surface at its backside 20a as shown in FIG. 2.

The wafer 10 for backside illumination type solid imaging device according to the invention is mainly characterized to be a SOI wafer 10 obtained by forming a given active layer 40 on a support substrate 20 made of C-containing n-type semiconductor material through a chemical oxide film 30 having a thickness of not more than 1 nm as shown in FIG. 1(a). By adopting such a structure, the C atoms are taken into positions between silicon lattices in the support substrate 20 to promote precipitation of an oxygen-containing substance in a heat treatment step for producing the solid imaging device, and thus the oxygen precipitates can serve as a gettering site. As a result, when the wafer 10 is used for the backside illumination type solid imaging device 100, the occurrence of white defects and heavy metal contamination can be effectively suppressed as compared with the conventional imaging devices.

The components in the wafer 10 for backside illumination type solid imaging device according to the invention will be described below.

(Support Substrate)

The support substrate 20 of the invention is a substrate made of n-type semiconductor material, which is required to contain a given amount of C for developing the above effect. The semiconductor used in the support substrate 20 is not particularly limited as long as it satisfies the above properties. From a point that the substrate can be obtained relatively easily, there is used, for example, a substrate 20 made of silicon material containing an elementary atom of the Group 15 such as P, As, Sb or the like.

Also, as the support substrate 20 is preferably used a n-type carbon-containing substrate in view of strengthening the gettering ability. Further, the support substrate 20 is preferable to have a specific resistance of 0.5 to 100 Ω·cm.

Moreover, the C concentration of the support substrate 20 is preferable to be within a range of 1.0×10¹⁶ to 1.0×10¹⁷ atoms/cm³. When the C concentration is less than 1.0×10¹⁶ atoms/cm³, there is a fear that the gettering ability can not be developed sufficiently and the occurrence of white defects and heavy metal contamination can not be sufficiently suppressed, while when it exceeds 1.0×10¹⁷ atoms/cm³, the size of the oxygen precipitates is less than 50 nm and hence there is a fear that strain energy capable of gettering heavy metal can not be retained.

Since the wafer 10 of the invention is used in the backside illumination type solid imaging device 100, when it is used as a device as shown in FIG. 2, the support substrate 20 can be processed until the thickness becomes not more than 20 μm. The thickness of the support substrate in the conventional wafer used for the backside illumination type solid imaging devices is 40 to 150 μm, whilst in this invention, the thickness may be made to not more than 20 μm because the thickened SOI structure is used.

(Chemical Oxide Film)

Since the wafer 10 for backside illumination type solid imaging device according to the invention is SOI, a chemical oxide film 30 having a thickness of not more than 1 nm is formed on the support substrate 20. The formation of the chemical oxide film 30 brings about the electric insulation between the support substrate 20 and the active layer 40, enabling smaller parasitic capacitance and speedup of the device. Further, since the thickness of the chemical oxide film is as thin as not more than 1 μm, the chemical oxide film facilitates permeation of an impurity such as heavy metal or the like in an active layer 40 mentioned later and develops an effect of effectively gettering the impurity in the support substrate as a gettering site.

The chemical oxide film means an extremely thin oxide film with a thickness of not more than 1 nm formed on a surface of the wafer for support substrate 22 or the wafer for active layer 43 by a given chemical cleaning, for example, SC-1 cleaning (cleaning with hydrochloric acid, HCL:H₂O₂:H₂O=1:1:1) and SC-2 cleaning (cleaning with ammonia hydrogen peroxide solution, NH₄OH:H₂O₂: H₂O=1:1:1) after the removal of native oxide film formed on the wafer surface.

Although the method for forming the chemical oxide film 30 will be concretely described later, since it is bonded to either the support substrate 20 or the active layer 40 (the support substrate 20 in the case of FIG. 1(a)) at a state that the periphery thereof is oxidized as a whole, as shown in FIG. 1(a), a residual oxide film 31 remains around the support substrate 20 in addition to the chemical oxide film 30 at a bonding interface of the wafer 10 for back side illumination type solid imaging device according to the invention. When the wafer 10 is used in the imaging device 100, since it is subjected to the processing, the residual oxide film 31 is already removed.

(Active Layer)

The active layer 40 according to the invention is a layer formed on the chemical oxide film 30. In the invention, it is a device layer arranged with the photoelectric conversion device 50 and the charge transfer transistor 60 as shown in FIG. 2. Moreover, it is preferably formed by bonding a wafer for active layer to a wafer for support substrate from a viewpoint that SOI being less in the defects and having the active layer 40 usable for an imaging device can be obtained simply. The detail of the production method will be described later.

In FIG. 3 is schematically shown a cross-section of an epitaxial wafer as a wafer for active layer according to the invention. The active layer 40 is preferable to be an epitaxial layer 42 of Si formed on a substrate 41 for active layer made of C-containing n-type semiconductor material as shown in FIG. 3. The epitaxial layer 42 formed on the substrate 41 for active layer made of C-containing n-type semiconductor material can provide the active layer 40 being less in the defects and having a high quality owing to the gettering effect of the C-containing substrate 41 for active layer. Therefore, when the active layer 40 is formed on the chemical oxide film 30, the effect of suppressing the occurrence of white defects and heavy metal contamination can be further improved in the solid imaging device 100 according to the invention.

Furthermore, the C concentration in the substrate for active layer is preferable to be within a range of 1.0×10¹⁶ to 1.0×10¹⁷ atoms/cm³. When the C concentration is less than 1.0×10¹⁶ atoms/cm³ likewise the case of the support substrate 20, there is a fear that the gettering ability can not be sufficiently developed and hence the white defects and heavy metal contamination generated in the active layer 40 can not be sufficiently suppressed, while when it exceeds 1.0×10¹⁷ atoms/cm³, the size of the oxygen precipitates becomes minimal and it is difficult to retain strain energy required for the gettering and hence there is a fear that the gettering ability lowers.

Moreover, it is preferable that C atoms contained in the support substrate 20 are existent as a high carbon concentration region 21 just beneath an interface with the chemical oxide film 30 as shown in FIG. 1(b). The high carbon concentration region 21 means a region having locally a large C content wherein the C concentration in the support substrate 20 is within a range of 1.0×10¹⁶ to 1.0×10¹⁷ atoms/cm³. Since the high carbon concentration region 21 serves as a gettering sink effectively, the effect of suppressing the occurrence of white defects and heavy metal contamination can be further improved.

Moreover, as shown in FIG. 2, the backside illumination type solid imaging device 100 can be prepared when an embedded electrode (not shown) for transferring image data is connected to the pixels 70 including the wafer 10 for backside illumination type solid imaging device 10 of the invention. By the gettering effect of the wafer 10 for backside illumination type solid imaging device 10 according to the invention, it is made possible to provide the backside illumination type solid imaging device 100 being excellent in the ability of suppressing the occurrence of white defects and heavy metal contamination as compared with the conventional backside illumination type solid imaging device. In FIG. 2, an embedded wiring 61 is disposed in the charge transfer transistor 60 and further a substrate 80 is arranged as a base for the pixels 70.

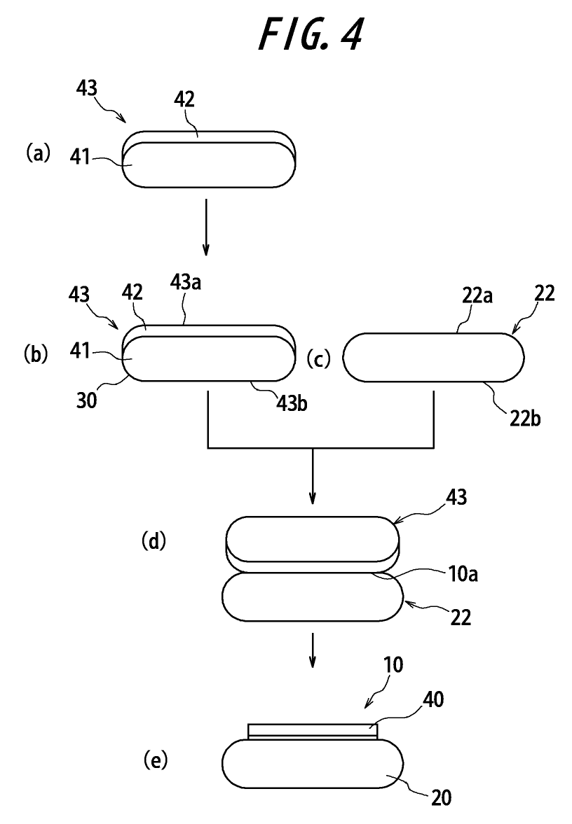

Subsequently, the method for producing the wafer for backside illumination type solid imaging device according to the invention will be described with reference to the accompanying drawings. FIG. 4 is a flow chart for explaining the method for producing the wafer for backside illumination type solid imaging device according to the invention.

As shown in FIG. 4, the wafer 10 for backside illumination type solid imaging device according to the invention is characterized by forming a chemical oxide film 30 having a thickness of not more than 1 nm on a surface of a wafer 43 for active layer (FIG. 4(a)), which is an epitaxial wafer obtained by forming an epitaxial film of Si on a substrate for active layer made of n-type semiconductor material preferably having a C concentration of 1.0×10¹⁶ to 1.0×10¹⁷ atoms/cm³, through a treatment such as thermal oxidation or the like (FIG. 4(b)), and thereafter bonding a wafer 22 for support substrate made of C-containing n-type semiconductor material (preferably C concentration: 1.0×10¹⁶ to 1.0×10¹⁷ atoms/cm³) (FIG. 4(c)) to the wafer 43 for active layer through the chemical oxide film 30 (FIG. 4(d)), and then thinning the wafer 43 for active layer to form SOI wafer 10 (FIG. 4(e)).

When the wafer 10 for backside illumination type solid imaging device is formed by the above method, the C atoms in the support substrate 20 are taken into positions between silicon lattices in the support substrate 20 to promote the precipitation of oxygen-containing substance in a heat treatment step for the production of the solid imaging device, and thus the oxygen precipitates can serve as a gettering site. As a result, when the wafer 10 is used for the backside illumination type solid imaging device 100, the occurrence of white defects and heavy metal contamination can be effectively suppressed as compared with the conventional imaging devices.

In FIG. 4, the chemical oxide film 30 is formed on the wafer 43 for active layer, which is merely one embodiment of the invention. In fact, it is also possible to form the chemical oxide film layer 30 on the wafer 22 for support substrate and then bond to the wafer 43. Also, the chemical oxide film 30 having a thickness of not more than 1 nm is formed by a given chemical cleaning, for example, SC-1 cleaning (cleaning with hydrochloric acid) and SC-2 cleaning (cleaning with ammonia hydrogen peroxide solution).

As a method of including a given amount of C into the wafer 22 for support substrate and the wafer 43 for active layer, there are a method of doping a silicon substrate with C atoms, a method of implanting ions and so on, whereby it is made possible to include the C atoms into the wafer 22 for support substrate.

Also, O atoms can be included into the wafer 22 for support substrate and the wafer 43 for active layer. The inclusion of the O atoms can effectively suppress the diffusion of the C atoms included for the gettering effect into the active layer.

Furthermore, it is preferable that each of the wafer 22 for support substrate and the wafer 43 for active layer is subjected to a heat treatment at 600 to 800° C. before the bonding of the wafers 22 and 43. Since the precipitation of oxygen is promoted by this heat treatment, it is possible to form high-density oxygen precipitates.

Moreover, it is preferable that the bonding is conducted after a given organic substance is adsorbed on bonding surfaces 22a, 43a of the wafer 22 for support substrate and/or the wafer 43 for active layer. When the bonding is conducted after the adsorption of the organic substance on the bonding surface(s) (FIG. 4(d)), the organic substance forms the high carbon concentration region 21 at the bonding interface 10a by the heat treatment in the bonding, and hence the further improvement of the gettering ability is expected in the wafer 10 according to the invention.

As the organic substance is preferable an organic carbon compound such as N-methyl pyrrolidone, polyvinyl pyrrolidone or the like. By using such an organic substance can be simply formed the high carbon concentration region 21.

In the production method of the invention, it is preferable that a polysilicon film (not shown) is formed on surfaces 22b, 43b opposite to the bonding surfaces 22a, 43a of the wafer 22 for support substrate and the wafer 43 for active layer, respectively. The resulting polysilicon film serves as a gettering sink, which is expected to further improve the gettering effect.

Although the above is described with respect to only one embodiment of the invention, various modifications may be made without departing from the scope of the appended claims.

A wafer for backside illumination type solid imaging device according to the invention is prepared as a sample and its performances are evaluated as described below.

### EXAMPLE 1

As shown in FIG. 4, there is provided an epitaxial wafer obtained by forming an epitaxial film of Si on a substrate 41 for active layer made of C-containing n-type silicon (C concentration: 1.0×10¹⁶ atoms/cm³, specific resistance: 10 Ω·cm) through a CVD method as a wafer 43 for active layer (FIG. 4(a)), and then a chemical oxide film 30 having a thickness of 0.5 nm is formed on the surface thereof by a thermal oxidation treatment (FIG. 4(b)). Thereafter, a wafer 22 for support substrate of n-type silicon made of C-containing n-type semiconductor material (C concentration: 1.0×10¹⁶ atoms/cm³, specific resistance: 10 Ω·cm) (FIG. 4(c)) is bonded to the wafer 43 for active layer through the chemical oxide film 30 (FIG. 4(d)), and then the wafer 43 for active layer is thinned by polishing and chemical etching to prepare a sample of a wafer 10 for backside illumination type solid imaging device as a SOI wafer having the given support substrate 20, chemical oxide film 30 and active layer 40 (FIG. 4(e)).

### EXAMPLE 2

A sample of a wafer 10 for backside illumination type solid imaging device is prepared in the same steps as in Example 1 (FIGS. 4(a) to (e)) except that an organic substance, N-methyl pyrrolidone is adsorbed on a bonding surface 22a of the wafer 22 for support substrate before the step of bonding the wafer 22 for support substrate to the wafer 43 for active layer (FIG. 4(d)) and then the bonding and heat treatment are conducted to form a high carbon concentration region 21 on a bonding interface 10a.

### EXAMPLE 3

A sample of a wafer 10 for backside illumination type solid imaging device is prepared in the same steps as in Example 1 (FIGS. 4(a) to (e)) except that a polysilicon film (not shown) is formed on surfaces 22b, 43b opposite to the bonding surfaces 22a, 43a of the wafer 22 for support substrate and the wafer 43 for active layer, respectively.

### COMPARATIVE EXAMPLE 1

A sample of a wafer for backside illumination type solid imaging device is prepared as a usual bonded SOI formed by bonding a wafer for support substrate made of Si (not including C) to a wafer for active layer made of Si through an oxide film and then removing a part of the wafer for active layer.

(Evaluation Method)

Each sample prepared in the above examples and comparative example is evaluated by the following evaluation methods.

(1) White Defects

A backside illumination type solid imaging device is prepared by using each sample prepared in the above examples and comparative example, and thereafter the dark leakage current of a photodiode in the backside illumination type solid imaging device is measured and converted to pixel data (number data of white defects) with a semiconductor parameter analyzing apparatus, whereby the number of white defects per unit area (cm²) is counted to evaluate the suppression on the occurrence of white defects. The evaluation standard is shown below, and the measured results and evaluation results are shown in Table 1.
⊚: not more than 5
◯: more than 5 but not more than 50
×: more than 50

(2) Heavy Metal Contamination

A defect density (defect number/cm²) on the surface of the sample is measured by contaminating the sample surface with nickel (1.0×10¹² atoms/cm²) by a spin coat contaminating method and thereafter subjecting to a heat treatment at 900° C. for 1 hour and then selectively etching the surface of the sample. The evaluation standard is shown below, and the measured results and evaluation results are shown in Table 1.
: less than 5
∘: not less than 5 but less than 50
×: not less than 50

TABLE 1

| | | | Presence or | | | |
|---|---|---|---|---|---|---|
| | | | absence of high | | Evaluation results | |
| | C content (atoms/cm³) | | carbon | Presence or | | Heavy metal |
| | Support | | concentration | absence of | White defects | contamination |
| | substrate | Active layer | region | polysilicon film | Evaluation | Evaluation |
| Example 1 | 1.00E+16 | 1.00E+16 | — | — | ◯ | ◯ |
| Example 2 | 5.00E+16 | 5.00E+16 | presence | — | ⊚ | ⊚ |
| Example 3 | 7.00E+16 | 7.00E+16 | — | presence | ⊚ | ⊚ |
| Comparative | — | — | — | — | X | X |
| Example 1 | | | | | | |

As seen from the results of Table 1, Examples 1 to 3 can suppress the occurrence of white defects and heavy metal contamination as compared with Comparative Example 1. Furthermore, it is found that Examples 2 and 3 are high in the gettering ability and further higher in the effect of suppressing the occurrence of white defect and heavy metal contamination as compared to Example 1.

According to the invention, it is possible to provide a wafer for backside illumination type solid imaging device capable of effectively suppressing occurrence of white defects and heavy metal contamination, a production method thereof and a backside illumination type solid imaging device.

The embodiments of the invention in which an exclusive property or privilege is claimed are defined as follows:

1. A wafer for backside illumination type solid imaging device having a plurality of pixels inclusive of a photoelectric conversion device and a charge transfer transistor at its front surface side and a light receiving surface at its back surface side, characterized in that said wafer is a SOI wafer obtained by forming a given active layer on a support substrate made of C-containing n-type semiconductor material through a chemical oxide film having a thickness of not more than 1 nm.

2. A wafer for backside illumination type solid imaging device according to claim 1, wherein the active layer is an epitaxial layer of Si formed on a substrate for active layer made of C-containing n-type semiconductor material.

3. A wafer for backside illumination type solid imaging device according to claim 2, wherein a C concentration in each of the support substrate and the substrate for active layer is within a range of 1.0×10¹⁶ to 1.0×10¹⁷ atoms/cm³.

4. A wafer for backside illumination type solid imaging device according to claim 1, wherein C atoms contained in the support substrate are existent as a high carbon concentration region having a C concentration of 1.0×10¹⁶ to 1.0×10¹⁷ atoms/cm³ just beneath an interface with the chemical oxide film.

5. A wafer for backside illumination type solid imaging device according to claim 1, wherein the support substrate further contains P, As or Sb.

6. A backside illumination type solid imaging device comprising an embedded electrode for transferring image data connected to pixels of a wafer for backside illumination type solid imaging device as described in claim 1.

7. A method for producing a wafer for backside illumination type solid imaging device having a plurality of pixels inclusive of a photoelectric conversion device and a charge transfer transistor at its front surface side and a light receiving surface at its back surface side, characterized in that a silicon substrate is formed by bonding a wafer for support substrate made of C-containing n-type semiconductor material to a given wafer for active layer through a chemical oxide film having a thickness of not more than 1 nm and then thinning the wafer for active layer.

8. The method according to claim 7, wherein the wafer for active layer is an epitaxial wafer obtained by forming an epitaxial film of Si on a substrate for active layer made of C-containing n-type semiconductor material.

9. The method according to claim 8, wherein a C concentration in each of the support substrate and the substrate for active layer is within a range of 1.0×10¹⁶ to 1.0×10¹⁷ atoms/cm³.

10. The method according to claim 7, wherein each of the wafer for support substrate and the wafer for active layer is subjected to a heat treatment at 600 to 800° C. before bonding thereof.

11. The method according to claim 7, wherein the bonding is conducted after a given organic substance is adsorbed on a bonding surface of the wafer for support substrate and/or the wafer for active layer.

12. The method according to claim 11, wherein the organic substance is an organic carbon compound.

13. The method according to claim 7, wherein a polysilicon film is formed on each surface opposite to bonding surfaces of the wafer for support substrate and the wafer for active layer.
